(19) United States
(12) Patent Application Publication
(10) Pub. No.: US 2022/0019717 A1
(43) Pub. Date: Jan. 20, 2022

(54) MODEL CREATION DEVICE, MODEL CREATION METHOD, AND PROGRAM

(71) Applicant: ISUZU MOTORS LIMITED, Tokyo (JP)

(72) Inventors: Toshiyuki USUI, Fujisawa-shi, Kanagawa (JP); Hironori ARAKI, Fujisawa-shi, Kanagawa (JP)

(21) Appl. No.: 17/298,491

(22) PCT Filed: Nov. 13, 2019
(86) PCT No.: PCT/JP2019/044455

§ 371 Date: May 28, 2021

(30) Foreign Application Priority Data
Nov. 30, 2018 (JP) 2018-224796

(51) Int. Cl. G06F 30/27; G07C 5/00; G07C 5/08

(52) U.S. Cl. CPC G06F 30/27; G07C 5/0808; G07C 5/008

(57) ABSTRACT

A model creation device 11 includes a replacement information obtaining unit 111 that obtains replacement part information for identifying a replaced part of a vehicle, replacement date information indicating the date when the part was replaced, and vehicle identification information for identifying the vehicle, a first data obtaining unit 112 that obtains a measured data set including a plurality of measured data obtained by measuring the state of a vehicle from a plurality of vehicles in association with the vehicle identification information, and a model creation unit 114 that creates a failure prediction model by using the plurality of measured data included in a measured data set obtained from a vehicle having a problem in the result of the executed self-diagnosis as training data for failure occurrence, among the plurality of measured data sets corresponding to the plurality of pieces of vehicle identification information obtained by the replacement information obtaining unit 111.

### TECHNICAL FIELD

The present disclosure relates to a model creation device, a model creation method, and a program for creating a machine learning model for predicting a vehicle failure.

### BACKGROUND ART

A related art discloses a system for predicting a device failure. PTL 1 discloses a technique of periodically obtaining data indicating a state of a device, which is the target for the failure prediction and predicting a failure time based on the obtained data.

### CITATION LIST

### Patent Literature

PTL 1: JP-A-2009-217770

### SUMMARY OF INVENTION

### Technical Problem

In the related-art system, it is assumed that a failure is predicted by using a linear prediction method, a neuron method, or the like. By using these methods, it is possible to predict the possibility of failure occurrence but there is a problem that the prediction accuracy is insufficient, for example, when the action changes immediately before the failure occurs.

Therefore, the present disclosure has been made in view of these points and the object thereof is to provide a model creation device, a model creation method, and a program capable of improving the accuracy of predicting the probability that a vehicle part will fail within a predetermined period.

### Solution to Problem

According to a first aspect of the present disclosure, a model creation device includes: a replacement information obtaining unit that obtains replacement part information for identifying a part of a vehicle replaced, replacement date information indicating a date when the part was replaced, and vehicle identification information for identifying the vehicle; a data obtaining unit that obtains a measured data set including a plurality of measured data obtained by measuring a state of a vehicle from a plurality of vehicles in association with the vehicle identification information; and a model creation unit configured to create a failure prediction model by using the plurality of measured data, which is included in a measured data set obtained from a vehicle having a problem in a result of a self-diagnosis executed, as training data for failure occurrence, among the plurality of measured data sets corresponding to the plurality of pieces of vehicle identification information obtained by the replacement information obtaining unit.

The model creation unit may create the failure prediction model by using the plurality of measured data, which is included in the measured data set obtained from a vehicle having a problem in a result of the self-diagnosis executed within a predetermined prediction period before the replacement date indicated by the replacement date information, as the training data for failure occurrence.

The model creation unit may, among the plurality of measured data included in the measured data set obtained from the vehicle having the problem in the result of the self-diagnosis, create the failure prediction model by: using a plurality of measured data, which was obtained after obtaining the result of the self-diagnosis with the problem, as the training data for failure occurrence; and not using a plurality of measured data, which was obtained before obtaining the result of the self-diagnosis with the problem, as the training data for failure occurrence.

The model creation unit may create the failure prediction model by: receiving a designation of a type of self-diagnosis; and using the plurality of measured data, which is included in the measured data set obtained from a vehicle having a problem in a result of the self-diagnosis of the received type, as the training data for failure occurrence.

The model creation unit may create the failure prediction model by using the plurality of measured data, which is included in the measured data set obtained by a vehicle having a problem in a result of the self-diagnosis of a type corresponding to a type of the part indicated by the replacement part information, as the training data for failure occurrence.

According to a second aspect of the present disclosure, a model creation method executed by a computer may include: a step of obtaining replacement part information for identifying a part of a vehicle replaced, replacement date information indicating a date when the part was replaced, and vehicle identification information for identifying the vehicle; a step of obtaining a measured data set including a plurality of measured data obtained by measuring a state of a vehicle from a plurality of vehicles in association with the vehicle identification information; and a step of creating a failure prediction model by using a measured data set, which is obtained from a vehicle having a problem in a result of a self-diagnosis executed, as training data for failure occurrence, among the plurality of measured data sets corresponding to the obtained plurality of pieces of vehicle identification information.

According to a third aspect of the present disclosure, a program causes a computer to function as: a replacement information obtaining unit that obtains replacement part information for identifying a part of a vehicle replaced, replacement date information indicating a date when the part was replaced, and vehicle identification information for identifying the vehicle; a data obtaining unit that obtains a measured data set including a plurality of measured data obtained by measuring a state of a vehicle from a plurality of vehicles in association with the vehicle identification information; and a model creation unit configured to create a failure prediction model by using a measured data set, which is obtained from a vehicle having a problem in a result of a self-diagnosis executed, as training data for failure occurrence, among the plurality of measured data sets corresponding to the plurality of pieces of vehicle identification information obtained by the replacement information obtaining unit.

### Advantageous Effects of Invention

According to the present disclosure, it is possible to improve the accuracy of predicting the probability that a vehicle part will fail within a predetermined period.

### BRIEF DESCRIPTION OF DRAWINGS

FIG. 1 is a diagram for illustrating an outline of a failure prediction system.

FIG. 2 is a diagram for illustrating measured data output by a vehicle sensor.

FIG. 3 is a diagram showing a functional configuration of a model creation device and a failure prediction device.

FIG. 4 is a flowchart showing a processing flow for creating a failure prediction model in the failure prediction system.

FIG. 5 is a diagram showing a configuration of a model creation device and a failure prediction device according to a modification.

### DESCRIPTION OF EMBODIMENTS

{Overview of Failure Prediction System 1}

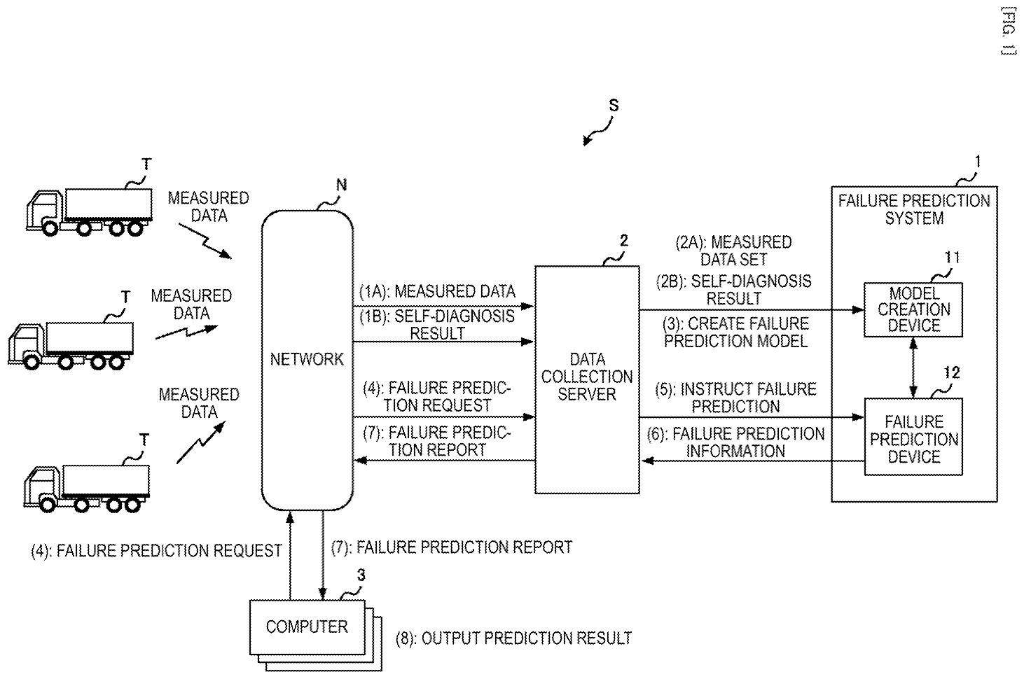

FIG. 1 is a diagram for illustrating an outline of a failure prediction system 1 according to the present embodiment. A vehicle management system S is a system for detecting an abnormal state of a vehicle T and predicting the probability that a part of the vehicle T will fail based on various data indicating the state of the vehicle T obtained from the vehicle T. The vehicle T is, for example, a commercial vehicle but the vehicle management system S may be applied to a vehicle other than a commercial vehicle. In the present specification, the description will be mainly made to the failure prediction system 1 that provides a function of predicting the probability that a part of the vehicle T will fail, among the functions of the vehicle management system S.

Each vehicle T is equipped with various sensors whose output values change depending on the state of various parts. The vehicle T is equipped with, for example, a sensor that detects the temperature of the engine, a sensor that detects the number of revolutions of the engine, a sensor that detects the temperature of the exhaust gas, and the like. The vehicle T transmits the output values of various sensors to a data collection server 2 via a network N such as a wireless communication network and the Internet. The vehicle T transmits the output values of various sensors in association with date and time information indicating the date and time.

In the following description, data indicating the output values of various sensors are referred to as measured data. A plurality of measured data is output from one sensor as time elapses. In the present specification, a plurality of measured data output from one sensor at a plurality of different dates and times is referred to as a measured data set. The data collection server 2 receives a plurality of measured data sets corresponding to one sensor from a plurality of vehicles T. That is, the data collection server 2 receives a plurality of measured data sets from a plurality of vehicles T.

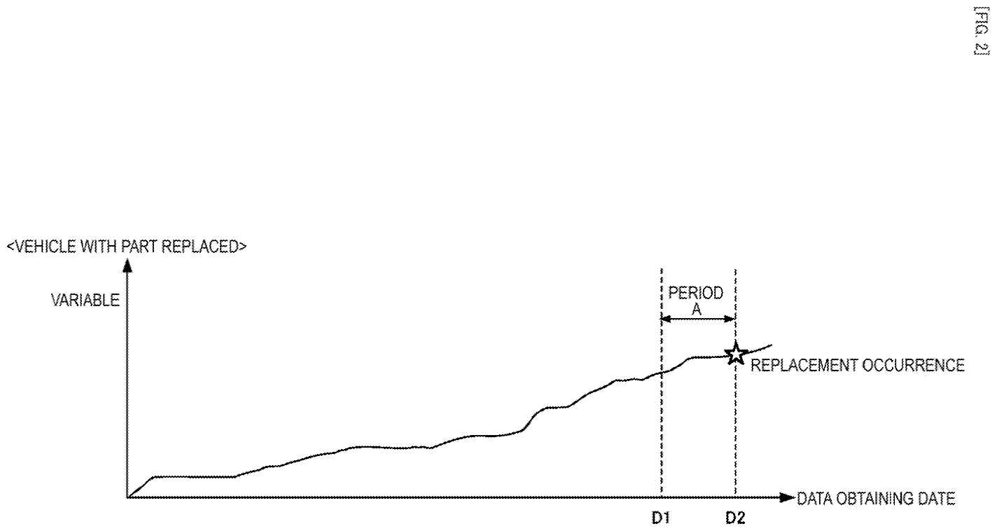

FIG. 2 is a diagram for illustrating measured data output by a sensor of the vehicle T. The horizontal axis in FIG. 2 represents the time elapsed since the vehicle T was manufactured, and the vertical axis represents the value of the variable corresponding to the measured data. FIG. 2 shows the values of variables corresponding to a plurality of measured data obtained since the time when the vehicle T was manufactured, in the vehicle T in which a part replacement has occurred. The variable is a numerical value indicating the characteristics of parts that can change over time, such as the temperature of the engine running under a predetermined condition. In the vehicle shown in FIG. 2, a failure has occurred at the time of D2.

The failure prediction system 1 obtains a measured data set including a plurality of measured data as shown in FIG. 2 in association with the type of measured data. The type of measured data is represented by the name of the sensor that outputs the measured data included in the measured data set, the name of the part related to the measured data, or the like. The failure prediction system 1 predicts the probability that a part of the vehicle T will fail within a predetermined prediction period, based on a plurality of obtained measured data sets. The predetermined prediction period is set to, for example, a number of days longer than the inspection interval of the vehicle T and is a period A between D1 and D2 in FIG. 2. If the inspection interval of the vehicle T is 90 days, the predetermined prediction period is, for example, 180 days.

The failure prediction system 1 uses the plurality of measured data included in the measured data set obtained from the vehicle T in which a problem has occurred in the self-diagnosis result as training data for failure occurrence, which is training data corresponding to a case where a failure may occur within a predetermined prediction period. Although the details will be described later, the failure prediction system 1 uses, for example, a plurality of measured data obtained within the predetermined prediction period in the vehicle T in which a problem has occurred in the self-diagnosis result as training data for failure occurrence. The failure prediction system 1 may use a plurality of measured data obtained before the predetermined prediction period from the vehicle T in which a problem has occurred in the self-diagnosis result as training data for no failure occurrence corresponding to a case where there is no possibility that a failure will occur within the predetermined prediction period.

As shown in FIG. 1, the vehicle management system S includes the failure prediction system 1, the data collection server 2, and a computer 3.

The failure prediction system 1 is a system for predicting a failure of the vehicle T and includes one or more computers. The failure prediction system 1 creates a failure prediction model, which is a machine learning model to be used to predict the probability that a failure will occur to a designated vehicle T within a predetermined prediction period and outputs the result of predicting the probability that a failure will occur to the vehicle T within the predetermined period, based on the created failure prediction model. The failure prediction system 1 includes a model creation device 11 and a failure prediction device 12. The details of the model creation device 11 and the failure prediction device 12 will be described later.

The data collection server 2 is a computer that collects measured data from a plurality of vehicles T via the network N. The computer 3 is installed in, for example, a company that owns the vehicle T or a company that maintains the vehicle T. The computer 3 is used for a staff of these companies (hereinafter, may be referred to as a user) to access the data collection server 2 to refer to the measured data of a specific vehicle T, or used for the specific vehicle T to make a request to predict the probability that a failure will occur within a predetermined prediction period.

Hereinafter, with reference to FIG. 1, a description will be made to the outline of the procedure that the failure prediction system 1 creates a failure prediction model and predicts the probability that the vehicle T will fail within a predetermined prediction period based on the created failure prediction model.

In the vehicle T, various sensors are constantly operated and the output values of the various sensors are sampled at predetermined measuring intervals (for example, 10-second intervals). The data collection server 2 obtains measured data from each vehicle T at a predetermined time interval, or, for example, at a predetermined timing such as when the vehicle T enters the car barn and stores a plurality of measured data in association with the vehicle identification information for identifying the vehicle T (section (1A) in FIG. 1). The vehicle identification information is information unique to the vehicle T, for example, a serial number assigned to the vehicle T at the time of manufacturing the vehicle T or a vehicle number assigned to the vehicle T at the Road Transport Bureau.

Further, in the vehicle T, self-diagnosis is performed based on the values of various sensors. The self-diagnosis is performed by constantly measuring the output values of various sensors and comparing the measured results with the reference values. In the self-diagnosis, the output value of the sensor corresponding to the measured data transmitted to the data collection server 2 may be used or data different from the output value of the sensor corresponding to the measured data may be used.

The results of self-diagnosis are classified into a plurality of stages. For example, the self-diagnosis result is classified into four stages, such as “good”, “fairly good”, “somewhat problematic”, and “significant problematic”. The vehicle T transmits the result of the self-diagnosis to the data collection server 2 (section (1B) in FIG. 1). The vehicle T may transmit the self-diagnosis result at the timing of transmitting the measured data or may transmit the self-diagnosis result at a timing different from the timing of transmitting the measured data.

The vehicle T may transmit the self-diagnosis result at the timing when the self-diagnosis result with a problem occurs. The data collection server 2 stores the received self-diagnosis result in association with the vehicle identification information. A state in which there is a problem in the self-diagnosis result is a state in which the state indicated by the self-diagnosis result is worse than the reference value. If the self-diagnosis result is classified into four stages, for example, “good”, “fairly good”, “somewhat problematic”, and “significant problem”, the self-diagnosis result corresponding to “somewhat problematic” or “significant problem” is a state having a problem in the self-diagnosis result.

If the data collection server 2 receives a request for a measured data set from the failure prediction system 1, the data collection server 2 provides the failure prediction system 1 with a plurality of measured data sets of the vehicle T. For example, in response to the request from the failure prediction system 1, the data collection server 2 transmits the measured data set and the self-diagnosis result to the failure prediction system 1 in association with the vehicle identification information of the vehicle T, at the timing when the failure prediction system 1 creates a failure prediction model (sections (2A) and (2B) in FIG. 1). The model creation device 11 creates a failure prediction model using the measured data set selected based on the self-diagnosis result as training data, among the measured data sets obtained from the data collection server 2 (section (3) in FIG. 1). The model creation device 11 creates a failure prediction model by using, for example, the measured data set obtained by the vehicle T having a problem in the self-diagnosis result as training data, among the measured data sets obtained from the data collection server 2.

After that, when the user of the computer 3 performs an operation of requesting a failure prediction via the application software installed on the computer 3 or the web application software provided by the failure prediction system 1, the computer 3 transmits a failure prediction request message including the vehicle identification information of the vehicle T, which is the target for the failure prediction to the data collection server 2 via the network N (section (4) in FIG. 1). Upon receiving the failure prediction request message, the data collection server 2 transmits a failure prediction instruction including the measured data set associated with the vehicle identification information included in the failure prediction request message to the failure prediction device 12 (section (5) in FIG. 1).

Upon receiving the failure prediction instruction, the failure prediction device 12 inputs the measured data set included in the failure prediction instruction into the failure prediction model created by the model creation device 11 to calculate the probability that a failure will occur to the vehicle T within the predetermined period. The failure prediction device 12 transmits the calculated probability value as a failure prediction result to the data collection server 2 (section (6) in FIG. 1). The data collection server 2 transmits a prediction result report including the failure prediction result received from the failure prediction device 12 to the computer 3 (section (7) in FIG. 1).

The computer 3 outputs the received prediction result report so that the user of the computer 3 can see the prediction result report (section (8) in FIG. 1). By the above procedure, a staff of the company that owns the vehicle T or a staff of the company that maintains the vehicle T can grasp the probability that a part of the vehicle will fail within a predetermined period.

Hereinafter, the configuration and operation of the failure prediction system 1 will be described in detail.

{Configuration of Failure Prediction System 1}

The model creation device 11 is a computer that uses the changing pattern of the plurality of measured data included in each of the plurality of obtained measured data sets as training data to generate a failure prediction model, which is a machine teaming model that outputs the probability that the vehicle T will fail within a predetermined prediction period, in response to the input of the measured data set obtained from the vehicle T, which is the target for the failure prediction.

The failure prediction system 1 uses, among the plurality of measured data included in the measured data set shown in FIG. 2, a plurality of measured data obtained from the vehicle T having a problem in at least a part of the self-diagnosis result within a predetermined number of days (for example, period A in FIG. 2) from the date when the part replacement has occurred (D2 in FIG. 2) as training data indicating that there is a possibility that a failure will occur within a predetermined prediction period. Among the plurality of measured data included in the measured data set shown in FIG. 2, the failure prediction system 1 uses a plurality of measured data obtained before a predetermined number of days from the date when the part replacement has occurred as training data for no failure occurrence indicating that there is no possibility that a failure will occur within a predetermined prediction period.

The failure prediction device 12 is a computer that outputs a prediction result indicating the probability that the vehicle T will fail within a predetermined prediction period based on the measured data set obtained from the vehicle T, which is the target for the failure prediction. The failure prediction device 12 inputs the measured data set obtained from the data collection server 2 to the model creation device 11 and outputs failure prediction information including a prediction result, which is a value indicating the probability of failure occurrence output from the model creation device 11. The failure prediction device 12 outputs the prediction result by displaying the failure prediction information on a display, printing the failure prediction information on paper, or transmitting the failure prediction information to another computer.

The details of the operation of the model creation device 11 will be described below.

{Functional Configuration and Operation of Model Creation Device 11}

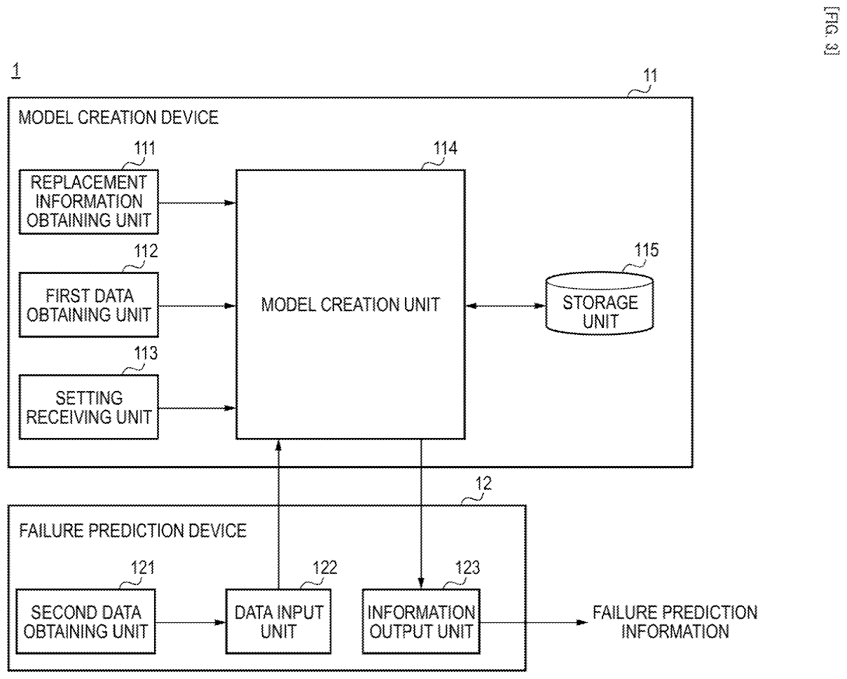

FIG. 3 is a diagram showing a functional configuration of the model creation device 11 and the failure prediction device 12. First, the functional configuration of the model creation device 11 will be described.

The model creation device 11 includes a replacement information obtaining unit 111, a first data obtaining unit 112, a setting receiving unit 113, a model creation unit 114, and a storage unit 115. The replacement information obtaining unit 111, the first data obtaining unit 112, the setting receiving unit 113, and the model creation unit 114 are composed of, for example, a central processing unit (CPU). The CPU reads various programs from a memory (for example, the storage unit 115) and executes the programs.

The replacement information obtaining unit 111 obtains replacement part information for identifying a replaced part of the vehicle T, replacement date information indicating the date when the part was replaced, and vehicle identification information for identifying the vehicle T in which the part has been replaced. The replacement information obtaining unit 111 obtains, for example, claim information, replacement part information, replacement date information, and vehicle identification information transmitted from the computer 3 of the sales company of the vehicle T, the company that owns the vehicle T, or the company that maintains the vehicle T, via the network N. The replacement information obtaining unit 111 obtains the replacement part information, replacement date information, and vehicle identification information input by a staff of the company where the failure prediction system 1 is installed by using the keyboard or touch panel of the computer 3.

The replacement part information is, for example, text information indicating the name of the replaced part, a number assigned to the replaced part, or image information indicating the shape of the replaced part. The replacement information obtaining unit 111 stores the obtained replacement part information and replacement date information in the storage unit 115 in association with the vehicle identification information.

The first data obtaining unit 112 obtains the measured data set including the plurality of measured data obtained by measuring the state of the vehicle T and the self-diagnosis result in association with the vehicle identification information of the vehicle T. The first data obtaining unit 112 obtains a plurality of measured data sets obtained since the time when the vehicle T was manufactured.

The first data obtaining unit 112 obtains the measured data set in association with data identification information for identifying what the plurality of measured data included in the measured data set has measured, for example, via the data collection server 2. The data identification information is, for example, text information indicating the name of a part to which the measured data is related, text information indicating the name of the sensor that has output the measured data, or a number assigned to the part or the sensor. In addition, the first data obtaining unit 112 obtains the self-diagnosis result in association with the date and time when the self-diagnosis was performed. The first data obtaining unit 112 stores the obtained measured data set and the self-diagnosis result in the storage unit 115 in association with the vehicle identification information.

The setting receiving unit 113 receives various settings input by a staff of the company that manages the failure prediction system 1 using a keyboard or a touch panel. As an example, the setting receiving unit 113 receives the setting of a prediction period, which is the period for which the failure prediction system 1 is to output the magnitude of the probability that a failure will occur. The setting receiving unit 113 displays, for example, candidates for a prediction period such as “90 days”, “180 days”, “270 days”, and “360 days” on the display and sets the candidate selected by the staff as a prediction period. When the staff does not set a prediction period, the setting receiving unit 113 may set a default value (for example, 180 days) as a prediction period or may set all candidates as prediction periods.

The model creation unit 114 creates a failure prediction model used for predicting the probability that a specific vehicle T will fail within a predetermined prediction period. Specifically, the model creation unit 114 creates a failure prediction model that outputs a prediction result of the probability that the vehicle T will fail within a predetermined prediction period when the measured data set obtained from the vehicle T, which is the target for the failure prediction is input.

The model creation unit 114 uses any algorithm for learning, but the model creation unit 114 inputs a large number of measured data sets (for example, hundred thousand types of measured data sets) to a known feature extraction algorithm or a known feature selection algorithm to narrow down the measured data sets and creates a failure prediction model based on the measured data sets after the narrowing down. The details of the operation of the model creation unit 114 will be described later.

The storage unit 115 is a storage medium such as a hard disk, a read only memory (ROM), and a random access memory (RAM). The storage unit 115 stores the replacement part information and the replacement date information obtained by the replacement information obtaining unit 111, and the measured data set obtained by the first data obtaining unit 112 in association with the vehicle identification information. Further, the storage unit 115 stores the failure prediction model created by the model creation unit 114. In addition, the storage unit 115 stores a program to be executed by the CPU that functions as the replacement information obtaining unit 111, the first data obtaining unit 112, the setting receiving unit 113, and the model creation unit 114. The storage unit 115 may be a storage medium readable by a computer.

{Details of Process of Creating Failure Prediction Model}

The model creation unit 114 uses, among the plurality of measured data sets corresponding to the plurality of pieces of vehicle identification information obtained by the replacement information obtaining unit 111, the plurality of measured data sets obtained within a predetermined prediction period before the replacement date indicated by the replacement date information (for example, the measured data sets in the period A in FIG. 2) as training data for failure occurrence. In addition, the model creation unit 114 uses the plurality of measured data sets obtained before a predetermined prediction period as training data for no failure occurrence. The model creation unit 114 creates a failure prediction model by using the plurality of measured data included in the measured data set obtained by the vehicle r having a problem in the result of the executed self-diagnosis as training data for failure occurrence, among the plurality of measured data sets corresponding to the plurality of pieces of vehicle identification information obtained by the replacement information obtaining unit Ill.

The model creation unit 114 uses the measured data set of the vehicle T having a problem in the self-diagnosis result as training data for failure occurrence, and thus, the plurality of measured data included in the measured data set obtained by the vehicle T in which the part replacement has occurred due to the accidental failure or the vehicle T in which the part replacement has occurred even though the part did not fail is not used as training data for failure occurrence. Therefore, the accuracy of the failure prediction is improved.

The model creation unit 114 may create a failure prediction model by using the plurality of measured data sets obtained from the vehicle T having a problem in the result of the self-diagnosis executed within a predetermined prediction period before the replacement date indicated by the replacement date information as training data for failure occurrence. By operating the model creation unit 114 in this way, the measured data of the vehicle T whose state has improved after there was a problem in the self-diagnosis result is not used as training data for failure occurrence, and thus, the accuracy of the failure prediction is further improved.

The model creation unit 114 may use the plurality of measured data obtained after the self-diagnosis result with a problem was obtained as training data for failure occurrence and may not use the plurality of measured data obtained before the self-diagnosis result with a problem was obtained as training data for failure occurrence, among the plurality of measured data included in the measured data set obtained by the vehicle T having a problem in the result of the executed self-diagnosis. By operating the model creation unit 114 in this way, the measured data at the time when no problem occurs in the self-diagnosis result is not used as training data for failure occurrence. Thus, when predicting a failure using the failure prediction model, the probability of being mistakenly predicted to have a high probability of failure despite the low probability of failure is reduced.

The model creation unit 114 may use a specific type of self-diagnosis result among a plurality of types of self-diagnosis results to determine whether or not to use the measured data set as training data for failure occurrence. For example, the model creation unit 114 receives the designation of a predetermined self-diagnosis type and uses the plurality of measured data included in the measured data set obtained by the vehicle T having a problem in the received type of predetermined self-diagnosis as training data for failure occurrence to create a failure prediction model.

The model creation unit 114 may create a failure prediction model by using the plurality of measured data included in the measured data set obtained by the vehicle T having a problem in the predetermined self-diagnosis of the type corresponding to the part type indicated by the replacement part information as training data for failure occurrence. For example, when a part related to the engine has been replaced, with a condition that the self-diagnosis result related to the engine is worse than the average stage, the model creation unit 114 uses the plurality of measured data included in the measured data set obtained by the vehicle T in which the corresponding self-diagnosis result was obtained as training data for failure occurrence. By operating the model creation unit 114 in this way, a failure prediction model is created based on the plurality of measured data sets obtained from the vehicle T in which there is a sign that a replaced part has deteriorated, and thus, the accuracy of failure prediction using the prediction model is improved.

The model creation unit 114 may create a failure prediction model for each usage mode of the vehicle T. The usage mode is the usage of the vehicle T which may affect the lifetime of the parts of the vehicle T, such as the average mileage per day, the average load, the traveling area, and the like. The first data obtaining unit 112 obtains usage mode data indicating the usage mode of the vehicle T in association with the vehicle identification information so that the model creation unit 114 can create a failure prediction model for each usage mode.

The model creation unit 114 creates a cluster of a plurality of measured data sets of normal vehicles by clustering based on usage mode data using only vehicles in which a failure has not occurred (for example, normal vehicles in which the parts have not been replaced and the replacement part information has not been obtained). Further, the model creation unit 114 allocates vehicles in which the part replacement has occurred (for example, failed vehicles in which parts have been replaced and the replacement part information has been obtained) to a cluster created with the measured data of the normal vehicle having the closest usage mode to create a measured data set for each cluster including a measured data set for a normal vehicle and a measured data sets for a failed vehicle. The model creation unit 114 creates a failure prediction model corresponding to each of the plurality of types of usage mode data by using the measured data set of the normal vehicle belonging to the cluster and the measured data set of the failed vehicle as training data for each cluster.

In this way, the model creation unit 114 creates a failure prediction model for each cluster, so that even if the lifetime of the part differs depending on the usage mode, the failure prediction system 1 can predict the probability of the failure occurrence within a predetermined prediction period with high accuracy. Further, by using only normal vehicles for clustering, it is possible to create a usage mode cluster that excludes the characteristics of usage modes that a failed vehicle may have. In the case of creating a failure prediction model for each type of parts described later, a normal vehicle is a vehicle in which a failure has not occurred in a part of the type for which a model is to be created, and a failed vehicle is a vehicle in which replacement has occurred in a part of the type for which a model is to be created.

The model creation unit 114 may create a failure prediction model corresponding to each of at least a part of the plurality of parts of the vehicle T. In this case, the model creation unit 114 uses, among the plurality of measured data sets included in the measured data set obtained by the first data obtaining unit 112, the plurality of measured data sets associated with the part corresponding to the failure prediction model as training data. When the model creation unit 114 creates a failure prediction model corresponding to the engine of the vehicle T, for example, the measured data set indicating the state of the engine such as a measured data set indicating the temperature of the engine and a measured data set indicating the number of revolutions of the engine is used as training data. The model creation unit 114 uses a known feature extraction algorithm or a known feature selection algorithm to narrow down the measured data sets from a large number of measured data sets for each part type and creates a failure prediction model for each part type based on the narrowed down measured data sets.

At this time, as described above, with a condition that there is a problem in the self-diagnosis result related to the part for which the failure prediction model is to be created, the model creation unit 114 creates a failure prediction model for the part based on the plurality of measured data sets obtained thereafter.

The model creation unit 114 may create a failure prediction model in association with a predetermined prediction period. The model creation unit 114 creates, for example, a failure prediction model that outputs the probability of failure before the prediction period elapses for each of a plurality of preset prediction periods.

When creating a failure prediction model corresponding to the prediction period of X days, for example, the model creation unit 114 uses the measured data set of X days immediately before the day when the part replacement has occurred (for example, a plurality of measured data obtained during the period A in FIG. 2) as training data for failure occurrence. The model creation unit 114 uses the measured data set before the X-th day from the day when the part replacement has occurred as training data for no failure occurrence. The model creation unit 114 may further use the measured data set corresponding to the vehicle T for which the replacement information obtaining unit Ill has not obtained the replacement part information among the plurality of measured data sets corresponding to the plurality of vehicles T obtained by the first data obtaining unit 112 as training data for no failure occurrence. The model creation unit 114 stores the created failure prediction model in the storage unit 115 in association with the prediction period.

The model creation unit 114 also has a function of calculating the probability that the vehicle T will fail within a prediction period by using the created failure prediction model. The model creation unit 114 obtains the measured data set of the vehicle T, which is the target for the failure prediction, for example, from the data collection server 2, for example, in response to the reception of the instruction from the failure prediction device 12 to predict a failure and inputs the obtained measured data set to the created failure prediction model. The model creation unit 114 outputs a value indicating the probability of failure occurrence output from the failure prediction model in response to the input of the measured data set to the failure prediction device 12 as a prediction result of the probability that the vehicle T will fail within the predetermined prediction period.

The model creation unit 114 may use the measured data set obtained as the target for predicting a failure as training data for updating the failure prediction model. For example, when the self-diagnosis result in the vehicle T corresponding to the obtained measured data set indicates the occurrence of a problem, the model creation unit 114 uses the measured data set obtained from the vehicle T as training data for failure occurrence and updates the failure prediction model.

The model creation unit 114 may obtain information indicating the history of past part replacement of the vehicle T corresponding to the obtained measured data set in association with the measured data set, and based on the information indicating the history, the plurality of measured data within the prediction period immediately before the date of part replacement in the measured data set having the history of part replacement may be used as training data for failure occurrence. In addition, the model creation unit 114 may use the plurality of measured data included in the measured data set having no history of part replacement as training data for a vehicle in which a failure has not occurred. The model creation unit 114 may use the plurality of measured data obtained in the vehicle T, which has no history of part replacement and whose self-diagnosis result is good, as training data for a vehicle in which a failure has not occurred.

Further, after the prediction period has elapsed since a failure of the vehicle T was predicted, the model creation unit 114 may obtain the information indicating whether or not a part of the vehicle T has been replaced during the prediction period via the replacement information obtaining unit 111 and compare the obtained information with the prediction result. The model creation unit 114 calculates the probability of failure within the prediction period based on the results of comparison for a large number of vehicles T, and if the difference between the calculated probability and the probability indicated by the prediction result is equal to or greater than a predetermined threshold value, the failure prediction model may be updated using the new measured data set as training data. By updating the failure prediction model with the model creation unit 114 in this way, the accuracy of the failure prediction model can be improved.

{Functional Configuration of Failure Prediction Device 12}

Subsequently, the functional configuration of the failure prediction device 12 will be described. The failure prediction device 12 includes a second data obtaining unit 121, a data input unit 122, and an information output unit 123.

The second data obtaining unit 121 obtains the measured data set of the vehicle T, which is the target for the failure prediction, and inputs the obtained measured data set to the data input unit 122. The second data obtaining unit 121 obtains the measured data set of the vehicle T, which is the target for the failure prediction, via the network N, together with the instruction of failure prediction. The second data obtaining unit 121 may obtain the measured data set from the data collection server 2 or the computer 3.

The data input unit 122 inputs the measured data set obtained from the second data obtaining unit 121 to the model creation unit 114. The data input unit 122 inputs the measured data set to the model creation unit 114 in association with the vehicle identification information of the vehicle T, which is the target for the failure prediction, for example. When the model creation unit 114 has a plurality of failure prediction models corresponding to a plurality of clusters, the data input unit 122 identifies the cluster corresponding to the measured data set obtained from the second data obtaining unit 121 and inputs the measured data set to the failure prediction model of the identified cluster.

The information output unit 123 obtains the prediction result output by the model creation unit 114 based on the measured data set input by the data input unit 122 to the model creation unit 114. The information output unit 123 obtains a prediction result from, for example, the failure prediction model corresponding to the cluster in which the data input unit 122 has input the measured data set, among the plurality of failure prediction models corresponding to the plurality of clusters. The information output unit 123 transmits the obtained prediction result to the source of the failure prediction instruction (for example, the data collection server 2 or the computer 3). The information output unit 123 may display the prediction result on the display included in the failure prediction device 12 or may print the prediction result on paper. The information output unit 123 may output the name of the cluster corresponding to the failure prediction model used for obtaining the prediction result together with the prediction result.

{Processing Flow in Failure Prediction System 1}

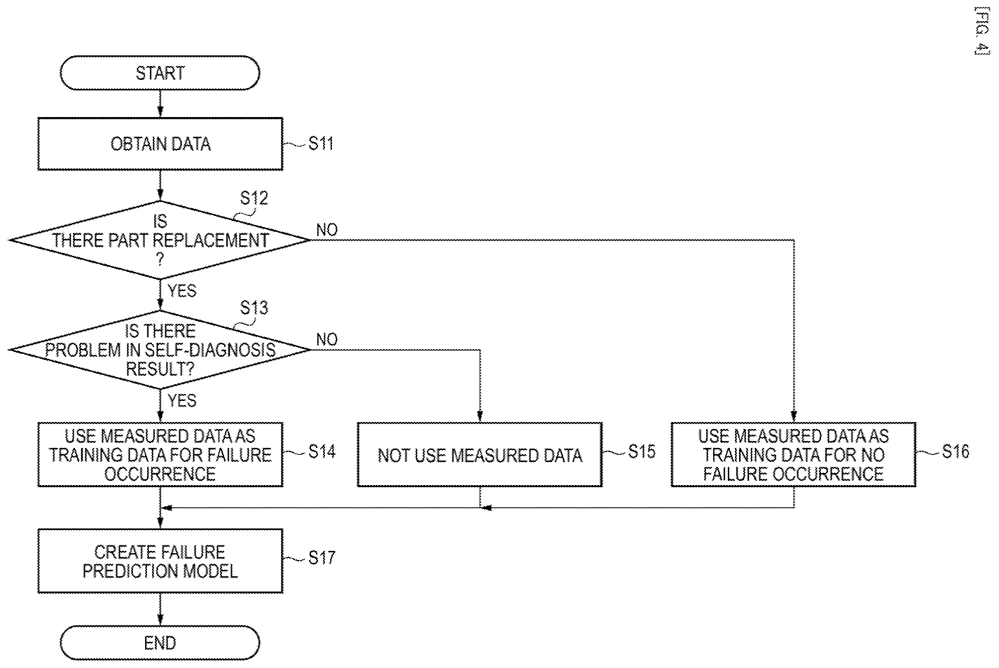

FIG. 4 is a flowchart showing a processing flow for creating a failure prediction model in the failure prediction system 1. Each of the following processes and each processing step of the flowchart indicates a CPU process according to a command described in a program such as a model creation program (for example, processes of the replacement information obtaining unit 111, the first data obtaining unit 112, and the model creation unit 114). First, the first data obtaining unit 112 obtains a plurality of measured data sets from a plurality of (for example, a large number) vehicles T in association with the vehicle identification information obtained by the replacement information obtaining unit 111 via the data collection server 2 (S11). Subsequently, the model creation unit 114 selects one measured data set from the plurality of measured data sets and specifies whether or not the part replacement has occurred in the vehicle T corresponding to the selected measured data set (S12). The model creation unit 114 also specifies the replacement date of the part when the part replacement has occurred.

When the model creation unit 114 determines in S12 that the part replacement has occurred (YES in S12), the model creation unit 114 determines whether or not a self-diagnosis result with a problem has occurred in the vehicle T in which the part replacement has occurred (S13). When the model creation unit 114 determines that a self-diagnosis result with a problem has occurred (YES in S13), the plurality of measured data obtained within a predetermined prediction period before the replacement date of the part are used as training data for failure occurrence, among the plurality of measured data included in the measured data set of the vehicle T (S14). When the model creation unit 114 determines that a self-diagnosis result with a problem has not occurred (NO in S13), the model creation unit 114 does not use the plurality of measured data included in the measured data set of the vehicle T as training data (S15).

When the model creation unit 114 determines in S13 that the part replacement has not occurred (NO in S12), the model creation unit 114 uses the selected measured data set as training data for no failure occurrence (S16). The model creation unit 114 may use a plurality of measured data before a predetermined prediction period as training data for no failure occurrence in which a failure does not occur within the prediction period.

The model creation unit 114 creates a failure prediction model by using a plurality of measured data as training data for failure occurrence or training data for no failure occurrence as determined in S14 and S15 (S17). The model creation unit 114 may execute the processes S11 to S17 and update the failure prediction model each time a new measured data set is obtained.

{First Modification}

In the above description, it is assumed that the failure prediction system 1 obtains the measured data set via the data collection server 2. Further, it was assumed that the failure prediction system 1 includes the model creation device 11 and the failure prediction device 12. However, the configurations of the model creation device 11 and the failure prediction device 12 are not limited thereto.

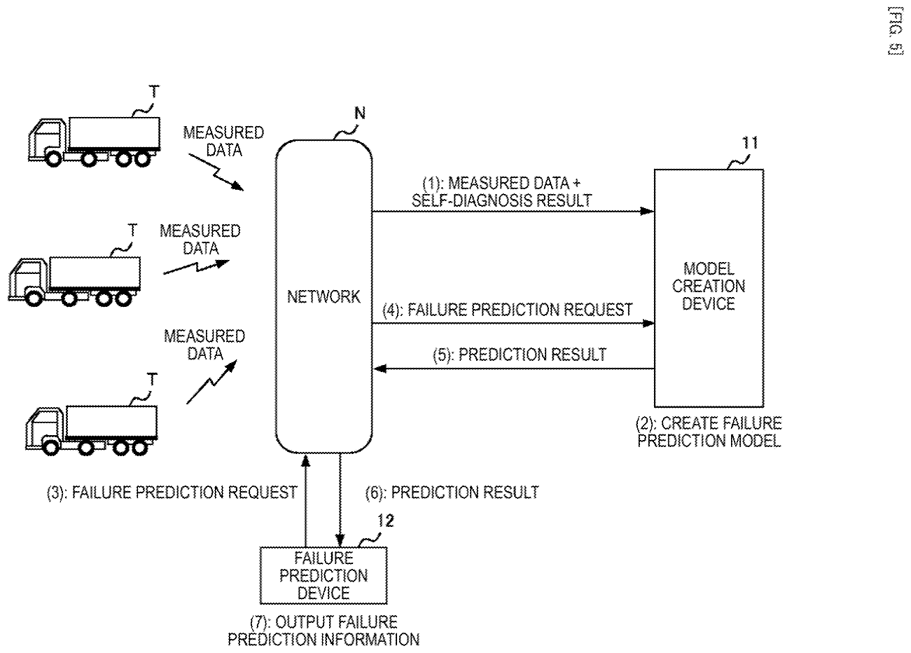

FIG. 5 is a diagram showing the configurations of the model creation device 11 and the failure prediction device 12 according to a first modification. The model creation device 11 shown in FIG. 5 obtains measured data and self-diagnosis results from a plurality of vehicles T via the network N (section (1) in FIG. 5) and creates a failure prediction model based on the obtained measured data (section (2) in FIG. 5).

Further, the failure prediction device 12 in FIG. 5 is set at a different location from the model creation device 11. The failure prediction device 12 executes the failure prediction function by, for example, executing an application program for failure prediction installed in a computer installed in a company that owns the vehicle T or a company that maintains the vehicle T. When the failure prediction device 12 transmits a failure prediction request to the model creation device 11 (sections (3) and (4) in FIG. 5) in response to the user's operation and receives a prediction result report output from the model creation device 11 (sections (5) and (6) in FIG. 5), the prediction result is output (section (7) in FIG. 5). As described above, the installation location and the connection relationship of the model creation device 11 and the failure prediction device 12 are arbitrary.

{Second Modification}

In the above description, the case where the model creation device 11 obtains the self-diagnosis result and the model creation device 11 identifies the vehicle T having a problem in the result of the executed self-diagnosis among the plurality of vehicles T has been exemplified. However, a device other than the model creation device 11 may identify the vehicle T having a problem in the result of the executed self-diagnosis. For example, the data collection server 2 may identify the vehicle T having a problem in the result of the executed self-diagnosis and transmit only the measured data set obtained by the identified vehicle T to the model creation device 11. By operating the data collection server 2 in this way, the amount of data transmitted by the data collection server 2 to the model creation device 11 is reduced, and the processing load of the model creation device 11 is reduced.

{Effect of Model Creation Device 11}

As described above, the replacement information obtaining unit Ill obtains the replacement part information for identifying a replaced part of the vehicle T, the replacement date information indicating the date when the part was replaced, and the vehicle identification information for identifying the vehicle T. The first data obtaining unit 112 obtains a measured data set including a plurality of measured data obtained by measuring the state of the vehicle T and a self-diagnosis result from the plurality of vehicles T in association with the vehicle identification information.

Then, the model creation unit 114 creates a failure prediction model by using the plurality of measured data included in the measured data set obtained by the vehicle having a problem in the result of the executed self-diagnosis as training data for failure occurrence, among the plurality of measured data sets corresponding to the plurality of pieces of vehicle identification information obtained by the replacement information obtaining unit 111. Since the model creation device 11 has such a configuration, the model creation device 11 can create a failure prediction model by using the measured data set obtained by the vehicle T having a problem in the self-diagnosis result among the plurality of vehicles T in which the part replacement has occurred. Therefore, it is possible to improve the accuracy of predicting the probability that a vehicle part will fail within a predetermined period.

In the above description, the model creation device 11 has created a failure prediction model that outputs the prediction result of the probability that the vehicle T will fail within a predetermined period, but as an example of the prediction result of the probability, the model creation device 11 may create a failure prediction model that outputs the probability that the vehicle Twill fail within a predetermined period as a prediction result. In this case, the failure prediction device 12 outputs information indicating the possibility that the vehicle T, which is the target for the failure prediction, will fail within a predetermined period as a prediction result.

Although the present invention has been described above using the embodiments, the technical scope of the present invention is not limited to the scope described in the above embodiments and various modifications and changes can be made within the scope of the gist thereof. For example, the present invention can be realized in the form of a computer program for realizing the functions of the model creation device and the model creation method, and a recording medium on which the computer program is recorded. Further, the specific embodiment of the distribution and integration of the device is not limited to the above-described embodiment, and all or a part of the embodiment can be functionally or physically distributed and integrated in any unit. Further, new embodiments resulting from any combination of a plurality of embodiments are also included in the embodiments of the present invention. The effect of the new embodiment produced by the combination has the effect of the original embodiment together.

The present application is based on a Japanese patent application filed on Nov. 30, 2018 (Japanese Patent Application No. 2018-224796), the contents of which are incorporated herein by reference.

### INDUSTRIAL APPLICABILITY

The present invention has the effect capable of improving the accuracy of predicting the probability that a vehicle part will fail within a predetermined period and is useful for a model creation device, a model creation method, a program, and the like.

### REFERENCE SIGNS LIST

1 Failure prediction system
2 Data collection server
3 Computer
11 Model creation device
12 Failure prediction device
111 Replacement information obtaining unit
112 First data obtaining unit
113 Setting receiving unit
114 Model creation unit
115 Storage unit
121 Second data obtaining unit
122 Data input unit
123 Information output unit

1. A model creation device comprising:
a controller configured to:
obtain replacement part information for identifying a part of a vehicle replaced, replacement date information indicating a date when the part was replaced, and vehicle identification information for identifying the vehicle;
obtain a measured data set including a plurality of measured data obtained by measuring a state of a vehicle from a plurality of vehicles in association with the vehicle identification information; and
create a failure prediction model by using the plurality of measured data, which is included in a measured data set obtained from a vehicle having a problem in a result of a self-diagnosis executed, as training data for failure occurrence, among the plurality of measured data sets corresponding to the plurality of pieces of obtained vehicle identification information obtained.

2. The model creation device according to claim 1, wherein in the creating, the controller is configured to:
create the failure prediction model by using the plurality of measured data, which is included in the measured data set obtained from a vehicle having a problem in a result of the self-diagnosis executed within a predetermined prediction period before the replacement date indicated by the replacement date information, as the training data for failure occurrence.

3. The model creation device according to claim 1, wherein in the creating, the controller is configured to:
among the plurality of measured data included in the measured data set obtained from the vehicle having the problem in the result of the self-diagnosis, create the failure prediction model by:
using a plurality of measured data, which was obtained after obtaining the result of the self-diagnosis with the problem, as the training data for failure occurrence; and
not using a plurality of measured data, which was obtained before obtaining the result of the self-diagnosis with the problem, as the training data for failure occurrence.

4. The model creation device according to claim 1, wherein in the creating, the controller is configured to create the failure prediction model by:
receiving a designation of a type of self-diagnosis; and
using the plurality of measured data, which is included in the measured data set obtained from a vehicle having a problem in a result of the self-diagnosis of the received type, as the training data for failure occurrence.

5. The model creation device according to claim 1, wherein the model creation unit in the creating, the controller is configured to:
create the failure prediction model by using the plurality of measured data, which is included in the measured data set obtained by a vehicle having a problem in a result of the self-diagnosis of a type corresponding to a type of the part indicated by the replacement part information, as the training data for failure occurrence.

6. A model creation method executed by a computer, the method comprising:
obtaining replacement part information for identifying a part of a vehicle replaced, replacement date information indicating a date when the part was replaced, and vehicle identification information for identifying the vehicle;
obtaining a measured data set including a plurality of measured data obtained by measuring a state of a vehicle from a plurality of vehicles in association with the vehicle identification information; and
creating a failure prediction model by using a measured data set, which is obtained from a vehicle having a problem in a result of a self-diagnosis executed, as training data for failure occurrence, among the plurality of measured data sets corresponding to the obtained plurality of pieces of vehicle identification information.

7. A non-transitory computer-readable medium storing a computer program readable by a computer, the computer program, when executed by the computer, causing a computer to perform:
obtaining replacement part information for identifying a part of a vehicle replaced, replacement date information indicating a date when the part was replaced, and vehicle identification information for identifying the vehicle;
obtaining a measured data set including a plurality of measured data obtained by measuring a state of a vehicle from a plurality of vehicles in association with the vehicle identification information; and
creating a failure prediction model by using a measured data set, which is obtained from a vehicle having a problem in a result of a self-diagnosis executed, as training data for failure occurrence, among the plurality of measured data sets corresponding to the plurality of pieces of obtained vehicle identification information.
